(19) United States
(12) Patent Application Publication
(10) Pub. No.: US 2006/0266288 A1
(43) Pub. Date: Nov. 30, 2006

(54) High plasma utilization for remote plasma clean

(75) Inventor: Soo Young Choi, Fremont, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/139,349

(22) Filed: May 27, 2005

(51) Int. Cl. C23C 16/00; B08B 6/00

(52) U.S. Cl. 118/715; 134/1.1; 118/723 R

(57) ABSTRACT

A method and apparatus for cleaning a chemical vapor deposition chamber are provided. The chemical vapor deposition chamber includes an inlet that introduces reactive species into the chamber from a remote plasma source while bypassing a gas distribution assembly of the chamber and an inlet that introduces reactive species from a remote plasma source into the chamber via the gas distribution assembly.

### BACKGROUND OF THE INVENTION

1. Field of the Invention

Embodiments of the present invention generally relate to a method of cleaning a chemical vapor deposition chamber. In particular, embodiments of the invention relate to a method of cleaning a chemical vapor deposition chamber for processing large area substrates.

2. Description of the Related Art

Chemical vapor deposition (CVD) is a commonly used method of depositing materials to form layers on substrates during the manufacture of integrated circuits and semiconductor devices. Chemical vapor deposition is typically performed by delivering gases to a substrate supported on a substrate support in a chemical vapor deposition chamber. The gases are delivered to the substrate through a gas distribution assembly in the chamber.

During chemical vapor deposition, deposited material is also formed on components of the chamber, such as the gas distribution assembly and the internal sidewalls of the chamber. This deposited material can flake off during subsequent processing and create contaminating particles that can damage or destroy components of the substrate in the chamber. Thus, periodic chamber cleaning is required.

Currently, one method of chamber cleaning uses a remote plasma source. The remote plasma source dissociates a cleaning gas into radicals or reactive species outside of the chamber. The reactive species are then flowed into the chamber to clean the chamber. By generating the reactive species remotely, the inside of the chamber is not exposed to the potentially damaging high levels of power needed to dissociate the cleaning gas.

It has been observed that chamber cleaning using a remote plasma source is often not as efficient as would be expected based on the estimated dissociation rate provided by the remote plasma source. Reactive species generated by remote plasma sources can recombine to form molecules that are less efficient in cleaning than the radicals. For example, the cleaning gas NF₃ may generate fluorine radicals that recombine to form F₂.

The extent of recombination can be estimated by comparing the pressure measured in a chemical vapor deposition chamber that receives gases from a remote plasma source in which the plasma power is turned on and the pressure measured in a chemical vapor deposition chamber that that receives gases from a remote plasma source in which the plasma power is turned off. The pressure should be higher in the chamber when the remote plasma power is on, as the plasma breaks one molecule into multiple reactive species that increase the chamber pressure. For example, a chamber that receives gases from a remote plasma source with the plasma power turned on to dissociate NF₃ should have a pressure 4 times the pressure of a chamber that receives undissociated NF₃ from a remote plasma source, since NF₃ dissociates into 1 nitrogen atom and 3 fluorine atoms. However, using current remote plasma sources and chemical vapor deposition chambers, the pressure of a chamber that receives gases from a remote plasma source with the plasma power turned on to dissociate NF₃ has a pressure that is only about 2 times the pressure of a chamber that receives undissociated NF₃ from a remote plasma source with the plasma power turned off. Thus, since the pressure of the chamber that receives gases from a remote plasma source with the plasma power turned on is about 50% of the expected pressure, it appears that approximately 50% of the reactive species are lost in the chamber due to recombination of the reactive species.

One cause of recombination is the restricted flow area provided by the gas distribution assembly of chemical vapor deposition chambers. The gas distribution assemblies typically contain a number of very small diameter holes through which the reactive species from the remote plasma source must pass in order to enter the processing region of the chamber. In such a small area, the reactive species are more likely to collide and recombine than in a larger area.

Low chamber cleaning efficiency resulting from recombination increases the amount of time required to clean a chamber, which reduces the substrate throughput of the chamber and increases the cost of the cleaning gas required to clean the chamber. The extra cleaning time required to sufficiently clean parts of the chamber, such as the edges and corners of the chamber, can result in damage by overetching to other parts of the chamber. Thus, there remains a need for a method and apparatus to more efficiently clean chemical vapor deposition chambers using a remote plasma source. In particular, there remains a need for a method and apparatus to more efficiently clean chemical vapor deposition chambers for processing large area substrates, e.g., substrates that are 1000 mm×1000 mm or larger, such as flat panel display substrates.

### SUMMARY OF THE INVENTION

The present invention generally provides a method and apparatus for cleaning a chemical vapor deposition chamber, such as a chemical vapor deposition chamber for processing large area substrates, such as flat panel display substrates. In one embodiment, a chemical vapor deposition system for processing flat panel display substrates comprises a chemical vapor deposition chamber comprising a chamber body, a substrate support, and a gas distribution assembly, wherein the chamber body defines a first inlet configured to provide reactive species from a remote plasma source into a processing region of the chemical vapor deposition chamber via the gas distribution assembly, and the chamber body defines one or more inlets configured to provide reactive species from the same or a different remote plasma source into the processing region of the chemical vapor deposition chamber while bypassing the gas distribution assembly.

In another embodiment, a chemical vapor deposition system for processing flat panel display substrates comprises a first remote plasma source and a chemical vapor deposition chamber connected to the remote plasma source, the chemical vapor deposition chamber comprising a chamber body, a substrate support, and a gas distribution assembly, wherein the chamber body defines a first inlet configured to provide reactive species from the first remote plasma source into a processing region of the chemical vapor deposition chamber via the gas distribution assembly, and the chamber body defines a second inlet configured to provide reactive species from the same or a different remote plasma source into the processing region of the chemical vapor deposition chamber while bypassing the gas distribution assembly.

In another embodiment, a chemical vapor deposition system for processing flat panel display substrates comprises a first remote plasma source; a second remote plasma source; a first chemical vapor deposition chamber connected to the first remote plasma source and the second remote plasma source, the first chemical vapor deposition chamber comprising a first chamber body, a first substrate support, and a first gas distribution assembly, wherein the first chamber body defines a first inlet configured to provide reactive species from the first remote plasma source into a processing region of the first chemical vapor deposition chamber via the first gas distribution assembly, and the first chamber body defines a second inlet configured to provide reactive species from the second remote plasma source into the processing region of the first chemical vapor deposition chamber while bypassing the first gas distribution assembly. The chemical vapor deposition system further comprises a second chemical vapor deposition chamber connected to the first remote plasma source and the second remote plasma source. The second chemical vapor deposition chamber comprises a second chamber body, a second substrate support, and a second gas distribution assembly, wherein the second chamber body defines a first inlet configured to provide reactive species from the first remote plasma source into a processing region of the second chemical vapor deposition chamber via the second gas distribution assembly, and the second chamber body defines a second inlet configured to provide reactive species from the second remote plasma source into the processing region of the second chemical vapor deposition chamber while bypassing the second gas distribution assembly.

In another embodiment, a method of cleaning a chemical vapor deposition chamber comprises introducing reactive species from a remote plasma source into the chemical vapor deposition chamber through a first inlet configured to provide reactive species from the remote plasma source into a processing region of the chemical vapor deposition chamber via a gas distribution assembly of the chemical vapor deposition chamber, and introducing reactive species from the same or a different remote plasma source into the processing region of the chemical vapor deposition chamber through a second inlet configured to provide reactive species from the same or a different remote plasma source into the processing region of the chemical vapor deposition chamber while bypassing the gas distribution assembly.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a plasma enhanced chemical vapor deposition system according to an embodiment of the invention.

FIG. 2 is a schematic cross-sectional view of a plasma enhanced chemical vapor deposition system according to another embodiment of the invention.

FIG. 3 is a schematic cross-sectional view of a plasma enhanced chemical vapor deposition system according to another embodiment of the invention.

FIG. 4 is a schematic cross-sectional diagram of a plasma enhanced chemical vapor deposition system according to another embodiment of the invention.

### DETAILED DESCRIPTION

Embodiments of the present invention provide a chemical vapor deposition system that includes a chemical vapor deposition chamber comprising a first inlet for providing reactive species from a remote plasma source into a processing region of the chamber via a gas distribution assembly of the chamber and a second inlet for providing reactive species from a remote plasma source into the processing region of the chamber without flowing the reactive species through the gas distribution assembly, i.e., while bypassing the gas distribution assembly.

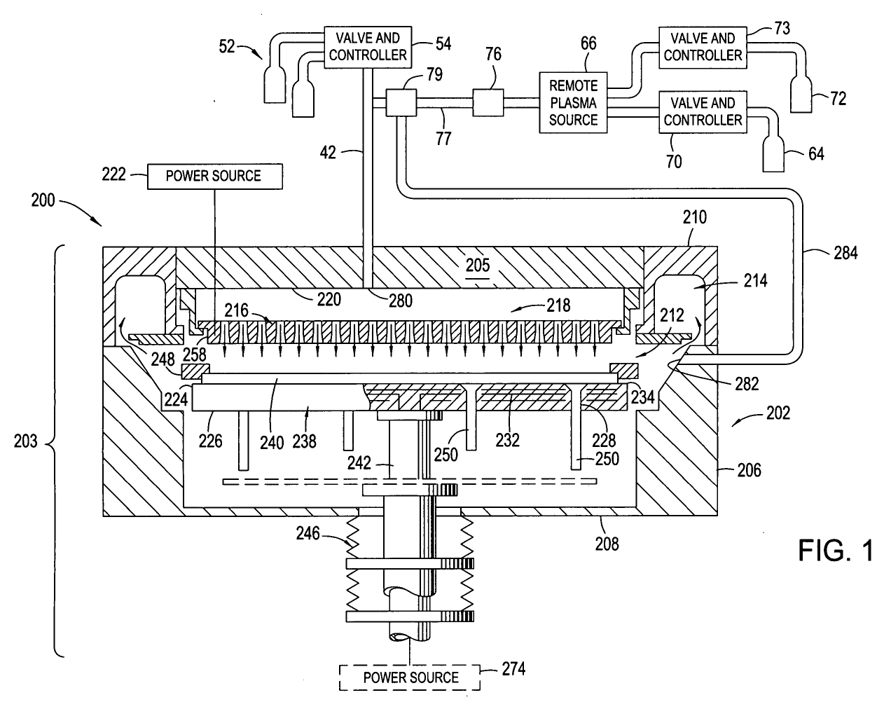

FIG. 1 is a schematic cross-sectional view of a plasma enhanced chemical vapor deposition system 200 according to an embodiment of the invention. The plasma enhanced chemical vapor deposition system 200 is similar to the plasma enhanced chemical vapor deposition system 4300, which is available from AKT, a division of Applied Materials, Inc., of Santa Clara, Calif. Other systems that may be modified according to embodiments of the invention include the 3500, 5500, 10K, 15K, 20K, 25K, and 40K chambers, also available from AKT, a division of Applied Materials, Inc. of Santa Clara, Calif. The system 200 generally includes a chemical vapor deposition chamber 203 coupled to a precursor supply 52. The chemical vapor deposition chamber 203 has sidewalls 206, a bottom 208, and a lid assembly 210 that define a processing volume or region 212 inside the chamber. The processing region 212 is typically accessed through a port (not shown) in the sidewalls 206 that facilitate movement of a substrate 240 into and out of the chemical vapor deposition chamber 203. The sidewalls 206 and bottom 208 are typically fabricated from aluminum, stainless steel, or other materials compatible with processing. The sidewalls 206 support a lid assembly 210 that contains a pumping plenum 214 that couples the processing region 212 to an exhaust system that includes various pumping components (not shown). The sidewalls 206, bottom 208, and lid assembly 210 define the chamber body 202.

A gas inlet conduit or pipe 42 extends into an entry port or inlet 280 in a central lid region of the chamber body 202 and is connected to sources of various gases. A precursor supply 52 contains the precursors that are used during deposition. The precursors may be gases or liquids. The particular precursors that are used depend upon the materials that are to be deposited onto the substrate. The process gases flow through the inlet pipe 42 into the inlet 280 and then into the chamber 203. An electronically operated valve and flow control mechanism 54 controls the flow of gases from the gas supply into the inlet 280.

A second gas supply system is also connected to the chamber through the inlet pipe 42. The second gas supply system supplies gas that is used to clean, e.g., remove deposited material, the inside of the chamber after one or more chemical vapor deposition processes have been performed in the chamber. In some situations, the first and second gas supplies can be combined.

The second gas supply system includes a source 64 of a cleaning gas (or liquid), such as nitrogen trifluoride or sulfur hexafluoride, a remote plasma source 66 which is located outside and at a distance from the chemical vapor deposition chamber, an electronically operated valve and flow control mechanism 70, and a conduit or pipe 77 connecting the remote plasma source to the chemical vapor deposition chamber 203. Such a configuration allows interior surfaces of the chamber to be cleaned using a remote plasma source.

The second gas supply system also includes one or more sources 72 of one or more additional gases (or liquids) such as oxygen or a carrier gas. The additional gases are connected to the remote plasma source 66 through another valve and flow control mechanism 73. The carrier gas aids in the transport of the reactive species generated in the remote plasma source to the deposition chamber and can be any nonreactive gas that is compatible with the particular cleaning process with which it is being used. For example, the carrier gas may be argon, nitrogen, or helium. The carrier gas also may assist in the cleaning process or help initiate and/or stabilize the plasma in the chemical vapor deposition chamber.

Optionally, a flow restrictor 76 is provided in the pipe 77. The flow restrictor 76 can be placed anywhere in the path between the remote plasma source 66 and the deposition chamber 203. The flow restrictor 76 allows a pressure differential to be provided between the remote plasma source 66 and the deposition chamber 203. The flow restrictor 76 may also act as a mixer for the gas and plasma mixture as it exits the remote plasma source 66 and enters the deposition chamber 203.

The valve and flow control mechanism 70 delivers gas from the source 64 into the remote plasma source 66 at a user-selected flow rate. The remote plasma source 66 may be an RF plasma source, such as an inductively coupled remote plasma source. The remote plasma source 66 activates the gas or liquid from the source 64 to form reactive species which are then flowed through the conduit 77 and the inlet pipe 42 into the deposition chamber through the inlet 280. The inlet 280 is, therefore, used to deliver the reactive species into the interior region of the chemical vapor deposition chamber 203 that includes the processing region 212.

The lid assembly 210 provides an upper boundary to the processing region 212. The lid assembly 210 includes a central lid region 205 in which the inlet 280 is defined. The lid assembly 210 typically can be removed or opened to service the chemical vapor deposition chamber 203. In one embodiment, the lid assembly 210 is fabricated from aluminum (Al). The lid assembly 210 includes a pumping plenum 214 formed therein coupled to an external pumping system (not shown). The pumping plenum 214 is utilized to channel gases and processing by-products uniformly from the processing region 212 and out of the chemical vapor deposition chamber 203.

The gas distribution assembly 218 is coupled to an interior side 220 of the lid assembly 210. The gas distribution assembly 218 includes a perforated area 216 in a gas distribution plate 258 through which gases, including reactive species generated by the remote plasma source and processing gases for chemical vapor deposition, are delivered to the processing region 212. The perforated area 216 of the gas distribution plate 258 is configured to provide uniform distribution of gases passing through the gas distribution assembly 218 into the process volume 212. Gas distribution plates that may be adapted to benefit from the invention are described in commonly assigned U.S. patent application Ser. No. 09/922,219, filed Aug. 3, 2001 by Keller, et al., now issued as U.S. Pat. No. 6,772,827; Ser. No. 10/140,324, filed May 6, 2002 by Yim, et al.; and Ser. No. 10/337,483, filed Jan. 7, 2003 by Blonigan, et al.; U.S. Pat. No. 6,477,980, issued Nov. 12, 2002 to White, et al.; and U.S. patent application Ser. No. 10/417,592, filed Apr. 16, 2003 by Choi, et al., which are hereby incorporated by reference in their entireties.

The gas distribution plate 258 is typically fabricated from stainless steel, aluminum (Al), anodized aluminum, nickel (Ni) or another RF conductive material. The gas distribution plate 258 is configured with a thickness that maintains sufficient flatness and uniformity so as to not adversely affect substrate processing. In one embodiment the gas distribution plate 258 has a thickness between about 1.0 inch to about 2.0 inches.

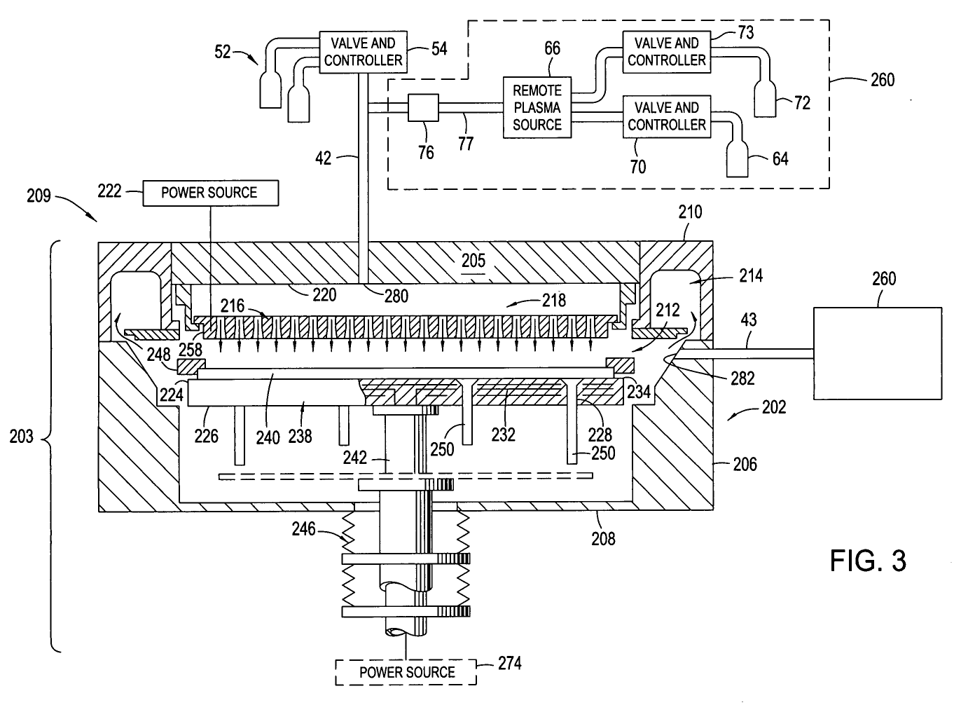

In addition to inlet 280, the chamber body 202 includes a second inlet 282 that provides reactive species from a remote plasma source. The remote plasma source may be the same remote plasma source 66 that provides reactive species to the processing region through the inlet 280 via the gas distribution assembly 218, as shown in FIG. 1, or a different remote plasma source, as shown and described below with respect to FIG. 3. Second inlet 282 is configured to provide reactive species from the remote plasma source into the processing region 212 of the chamber 203 while bypassing the gas distribution assembly 218. In other words, the reactive species provided by the second inlet 282 do not pass through the perforated gas distribution plate 258 of the gas distribution assembly 218. The second inlet may be located in a sidewall 206 of the chamber body 202 below the gas distribution assembly 218, such as between the gas distribution plate 258 and the substrate support 224. A gas line 284 from the remote plasma source to the second inlet 282 delivers reactive species from the remote plasma source to the processing region 212 of the chamber 203 through the second inlet 282.

Typically, a diverter 79 is provided in the gas line 77 from the remote plasma source. The diverter 79 allows a first portion of the reactive species from the remote plasma source 66 to be directed to the first inlet 280 of the chamber 203 via line 42 between the diverter 79 and the chamber 203 and a second portion of the reactive species from the remote plasma source to be directed to the second inlet 282 of the chamber via line 284 between the diverter 79 and the chamber 203.

A temperature controlled substrate support assembly 238 is centrally disposed within the chamber 203. The support assembly 238 supports a substrate 240 during processing. In one embodiment, the substrate support assembly 238 comprises a substrate support 224 having an aluminum body that encapsulates at least one embedded heater 232. The heater 232, such as a resistive element, disposed in the support assembly 238, is coupled to an optional power source 274 and controllably heats the support assembly 238 and the substrate 240 positioned thereon to a predetermined temperature.

Generally, the support assembly 238 has a substrate support 224 comprising a lower side 226 and an upper side 234. The upper side 234 supports the substrate 240. The lower side 226 has a stem 242 coupled thereto. The stem 242 couples the support assembly 238 to a lift system (not shown) that moves the support assembly 238 between an elevated processing position (as shown) and a lowered position that facilitates substrate transfer to and from the chemical vapor deposition chamber 203. The stem 242 additionally provides a conduit for electrical and thermocouple leads between the support assembly 238 and other components of the system 200.

A bellows 246 is coupled between support assembly 238 (or the stem 242) and the bottom 208 of the chemical vapor deposition chamber 203. The bellows 246 provides a vacuum seal between the processing region 212 and the atmosphere outside the chemical vapor deposition chamber 203 while facilitating vertical movement of the support assembly 238.

The support assembly 238 generally is grounded such that RF power supplied by a power source 222 to the gas distribution assembly 218 positioned between the lid assembly 210 and substrate support assembly 238 (or other electrode positioned within or near the lid assembly of the chamber) may excite gases present in the processing region 212 between the support assembly 238 and the gas distribution assembly 218. The support assembly 238 additionally supports a circumscribing shadow frame 248. Generally, the shadow frame 248 prevents deposition at the edge of the substrate 240 and support assembly 238 so that the substrate does not adhere to the support assembly 238. The support assembly 238 has a plurality of holes 228 disposed therethrough that accept a plurality of lift pins 250.

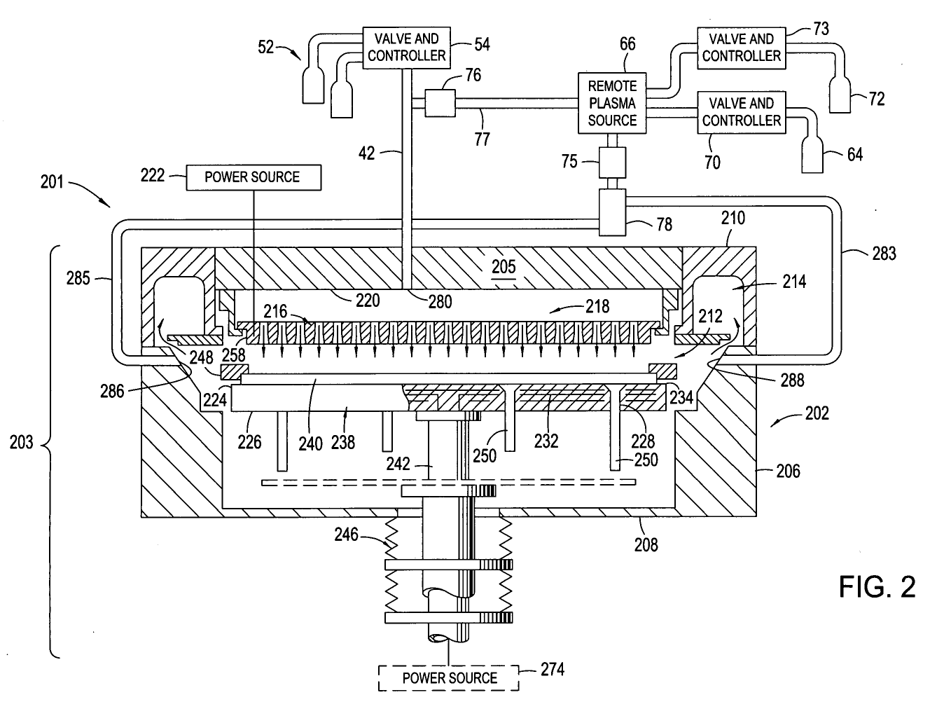

FIG. 2 is a schematic cross-sectional view of a plasma enhanced chemical vapor deposition system 201 according to another embodiment of the invention. As shown in FIG. 2, system 201 is similar to system 200 shown in FIG. 1 (identical components are labeled with the same reference numerals in FIGS. 1 and 2). However, system 201 includes two inlets 286, 288 that are configured to provide reactive species from a remote plasma source while bypassing the gas distribution assembly 218, while system 200 of FIG. 1 includes one inlet 282 configured to provide reactive species from a remote plasma source while bypassing the gas distribution assembly 218. A gas line 283 from the remote plasma source to the inlet 288 delivers reactive species from the remote plasma source to the processing region of the chamber 203 through the inlet 288. A gas line 285 from the remote plasma source to the inlet 286 delivers reactive species from the remote plasma source to the processing region of the chamber 203 through the inlet 286. Optionally, system 201 also comprises a second flow restrictor 75 such that there is an optional flow restrictor 76 between the remote plasma source 66 and the first inlet 280 and another optional flow restrictor 75 between the remote plasma source 66 and the inlets 286, 288. A diverter 78 between the flow restrictor 75 and the inlets 286, 288 controls the flow of reactive species from the remote plasma source 66 to the inlets 286, 288 such that a portion of the reactive species may be provided to the processing region 212 via inlet 286 and a portion of the reactive species may be provided to the processing region via inlet 288. The inlets 286, 288 may be located in the sidewalls 206 of the chamber body 202 on opposite sides of the chamber. It is believed that providing two spaced apart inlets 286, 288 enhances the formation of a uniform distribution of the reactive species across the chamber.

FIG. 3 is schematic cross-sectional view of a plasma enhanced chemical vapor deposition system 209 according to another embodiment of the invention. As shown in FIG. 3, system 209 is similar to system 200 shown in FIG. 1 (identical components are labeled with the same reference numerals in FIGS. 1 and 3). However, system 209 comprises two remote plasma sources. As shown schematically in FIG. 3, a first remote plasma assembly 260 comprising remote plasma source 66 and associated components, such as the flow control mechanism 70, 73, gas sources 64, 72, and optional flow restrictor 76 is connected to the chamber 203 via gas line 42, and a second remote plasma assembly 260 comprising a remote plasma source is connected to the chamber via gas line 43. Reactive species from gas line 42 are introduced into the chamber via inlet 280, and reactive species from gas line 43 are introduced into the chamber via inlet 282. Since the reactive species are introduced into inlets 280 and 282 from different remote plasma sources, a diverter is not required to regulate the flow between one remote plasma source and two inlets.

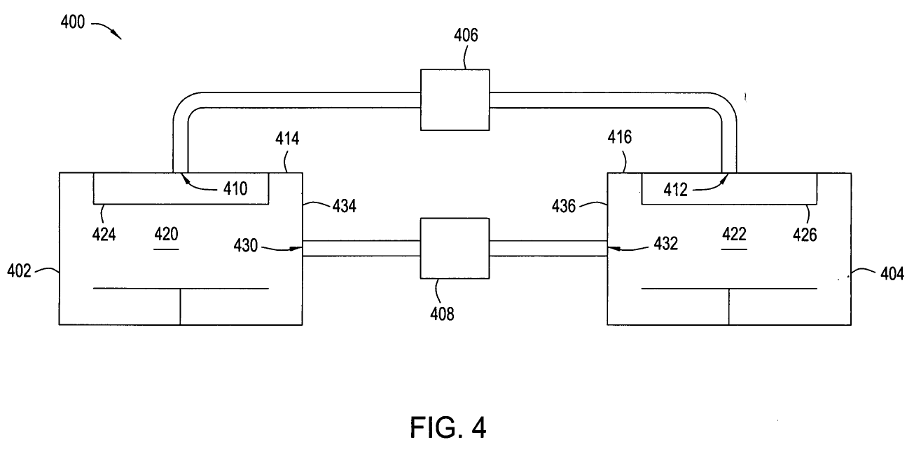

FIG. 4 is schematic cross-sectional diagram of a plasma enhanced chemical vapor deposition system 400 according to another embodiment of the invention. System 400 includes a first chemical vapor deposition chamber 402, a second chemical vapor deposition chamber 404, a first remote plasma source 406, and a second remote plasma source 408. The chemical vapor deposition chamber 402, second chemical vapor deposition chamber 404, first remote plasma source 406, and second remote plasma source 408 are summarized briefly in FIG. 4, and may contain some or all of the components of the chemical vapor deposition chambers and remote plasma sources described above with respect to FIGS. 1-3. Remote plasma source 406 provides reactive species to inlets 410, 412 in lid regions 414, 416 of chambers 402, 404 respectively. The reactive species enter the processing regions 420, 422 of chambers 402, 404 through gas distribution assemblies 424, 426. Remote plasma source 408 provides reactive species to inlets 430, 432 in sidewalls 434, 436 of chambers 402, 402 respectively. Thus, the reactive species from remote plasma source 408 bypass the gas distribution assemblies 424, 426.

The plasma enhanced chemical vapor deposition system shown in FIG. 4 reduces the number of remote plasma sources that are required to clean several chambers. For example, while the system shown in FIG. 3 includes two remote plasma sources per one chemical vapor deposition chamber, the system shown in FIG. 4 provides a method of cleaning two chemical vapor deposition chambers with two remote plasma sources. A deposition process may be performed in one of the chambers of the system shown in FIG. 4 while the other chamber is being cleaned with the two remote plasma sources. After the deposition process is completed in the first chamber, the two remote plasma sources may then be used to clean the first chamber, and a deposition process may be performed simultaneously in the other chamber.

While FIG. 4 illustrates an embodiment in which a first remote plasma source provides reactive species to processing regions of two chambers through the chambers' gas distribution assemblies and a second remote plasma source provides reactive species to the processing regions of the two chambers while bypassing the chambers' gas distribution assemblies, in other embodiments, other numbers of remote plasma sources and chambers may be used together. For example, a first remote plasma source may be coupled to a first inlet of three or more chambers, and a second remote plasma source may be coupled to a second inlet of three or more chambers.

As the plasma enhanced chemical vapor deposition systems provided according to embodiments of the invention include an inlet that introduces reactive species into a processing region of a chemical vapor deposition chamber while bypassing the gas distribution assembly of the chemical vapor deposition chamber, embodiments of the invention provide a method of cleaning a plasma enhanced chemical vapor deposition system that includes introducing reactive species from a remote plasma source into the processing region of the chemical vapor deposition chamber while bypassing the gas distribution assembly of the chemical vapor deposition chamber. Reactive species from either the same or a different remote plasma source may be introduced into the chamber through a separate inlet that is configured to provide the reactive species into the processing region of the chamber via the gas distribution assembly.

The reactive species may be formed from conventional cleaning gases, such as halogen-containing gases, e.g., fluorine-containing gases, such as NF₃, F₂, CF₄, SF₆, C₂F₆, CCl₄, C₂Cl₆, or combinations thereof, using standard remote plasma source conditions. In situ power provided by the chemical vapor deposition chamber, such as internal RF power, may also be used during the chamber cleaning process to enhance the cleaning rate by additionally decomposing species, such as F₂ species.

By providing at least some of the reactive species via the gas distribution assembly, the gas distribution assembly is cleaned or at least partially cleaned by the reactive species. Preferably, a majority of the reactive species that are introduced into the processing region of the chamber are introduced while bypassing the gas distribution assembly. For example, reactive species may be introduced into the processing region of the chamber through the first inlet and gas distribution assembly at a first flow rate, and reactive species may be introduced into the processing region of the chamber through the second inlet that bypasses the gas distribution assembly at a second flow rate that is between about 1 and about 10 times greater than the first flow rate. For example, the first flow rate may be about 2 slm, and the second flow rate may be about 10 slm for a modified AKT 25 K PECVD chamber.

While the reactive species may be introduced into the processing region of the chamber via the gas distribution assembly simultaneously with the introduction of reactive species into the processing region of the chamber while bypassing the gas distribution assembly, the introduction of reactive species through the different inlets in the chamber may be performed sequentially. For example, reactive species may be introduced into the processing region of the chamber through the first inlet and gas distribution assembly for a first period of time, such as a period of time sufficient to clean the perforations of the gas distribution assembly. The flow of the reactive species through the first inlet may then be terminated, and reactive species may be introduced into the processing region of the chamber through the second inlet that bypasses the gas distribution assembly for a second period of time to clean the other components of the chamber.

It is believed that providing a majority of the reactive species to the chamber while bypassing the gas distribution assembly increases chamber cleaning efficiency by reducing the amount of recombination of the active species caused flowing the reactive species through the small diameter (e.g., 16 mils) perforations of the gas distribution assembly.

While the foregoing is directed to embodiments of the present invention, other and further embodiments of the invention may be devised without departing from the basic scope thereof, and the scope thereof is determined by the claims that follow.

What is claimed is:

1. A chemical vapor deposition system for processing flat panel display substrates, comprising:
a chemical vapor deposition chamber comprising:
a chamber body;
a substrate support; and
a gas distribution assembly;
wherein the chamber body defines a first inlet configured to provide reactive species from a remote plasma source into a processing region of the chemical vapor deposition chamber via the gas distribution assembly, and the chamber body defines one or more inlets configured to provide reactive species from the same or a different remote plasma source into the processing region of the chemical vapor deposition chamber while bypassing the gas distribution assembly.

2. The chemical vapor deposition system of claim 1, wherein the second inlet is in a sidewall of the chamber body between the gas distribution assembly and the substrate support.

3. The chemical vapor deposition system of claim 1, wherein the first inlet is in a lid region of the chamber body.

4. The chemical vapor deposition system of claim 3, wherein the second inlet is in a sidewall of the chamber body below the gas distribution assembly.

5. The chemical vapor deposition system of claim 1, wherein the chamber body defines more than one inlet configured to provide reactive species from the same or a different remote plasma source into the processing region of the chemical vapor deposition chamber while bypassing the gas distribution assembly.

6. The chemical vapor deposition system of claim 1, wherein the chamber body defines two inlets configured to provide reactive species from the same or a different remote plasma source into the processing region of the chemical vapor deposition chamber while bypassing the gas distribution assembly, and the two inlets are located on opposite sides of the chemical vapor deposition chamber.

7. A chemical vapor deposition system for processing flat panel display substrates, comprising:
a first remote plasma source; and
a chemical vapor deposition chamber connected to the remote plasma source, the chemical vapor deposition chamber comprising:
a chamber body;
a substrate support; and
a gas distribution assembly;
wherein the chamber body defines a first inlet configured to provide reactive species from the first remote plasma source into a processing region of the chemical vapor deposition chamber via the gas distribution assembly, and the chamber body defines a second inlet configured to provide reactive species from the same or a different remote plasma source into the processing region of the chemical vapor deposition chamber while bypassing the gas distribution assembly.

8. The chemical vapor deposition system of claim 7, further comprising a flow restrictor adapted to provide a pressure differential between the first remote plasma source and the chemical vapor deposition chamber.

9. The chemical vapor deposition system of claim 7, further comprising a second remote plasma source connected to the chemical vapor deposition chamber, and wherein the second inlet is configured to provide reactive species from the second remote plasma source into the processing region of the chemical vapor deposition chamber while bypassing the gas distribution assembly.

10. The chemical vapor deposition system of claim 7, wherein the second inlet is configured to provide reactive species from the first remote plasma source into the processing region of the chemical vapor deposition chamber while bypassing the gas distribution assembly.

11. The chemical vapor deposition system of claim 7, further comprising a diverter in a gas line from the first remote plasma source to the chamber body, wherein the diverter is configured to provide a portion of the reactive species generated by the first remote plasma source to the first inlet and to provide a portion of the reactive species generated by the first remote plasma source to the second inlet.

12. The chemical vapor deposition system of claim 7, wherein the chamber body further defines a third inlet configured to provide reactive species from the same or a different remote plasma source into the processing region of the chemical vapor deposition chamber while bypassing the gas distribution assembly, wherein the second and third inlets are located on opposite sides of the chemical vapor deposition chamber.

13. A chemical vapor deposition system for processing flat panel display substrates, comprising:
a first remote plasma source;
a second remote plasma source;
a first chemical vapor deposition chamber connected to the first remote plasma source and the second remote plasma source, the first chemical vapor deposition chamber comprising:
a first chamber body;
a first substrate support; and
a first gas distribution assembly;
wherein the first chamber body defines a first inlet configured to provide reactive species from the first remote plasma source into a processing region of the first chemical vapor deposition chamber via the first gas distribution assembly, and the first chamber body defines a second inlet configured to provide reactive species from the second remote plasma source into the processing region of the first chemical vapor deposition chamber while bypassing the first gas distribution assembly; and
a second chemical vapor deposition chamber connected to the first remote plasma source and the second remote plasma source, the second chemical vapor deposition chamber comprising:
a second chamber body;
a second substrate support; and
a second gas distribution assembly;
wherein the second chamber body defines a first inlet configured to provide reactive species from the first remote plasma source into a processing region of the second chemical vapor deposition chamber via the second gas distribution assembly; and the second chamber body defines a second inlet configured to provide reactive species from the second remote plasma source into the processing region of the second chemical vapor deposition chamber while bypassing the second gas distribution assembly.

14. The chemical vapor deposition system of claim 13, wherein the second inlet in the first chamber body is in a sidewall of the first chamber body between the first gas distribution assembly and the first substrate support, and the second inlet in the second chamber body is in a sidewall of the second chamber body between the second gas distribution assembly and the second substrate support.

15. The chemical vapor deposition system of claim 13, further comprising a flow controller between each of the remote plasma sources and each of the chamber bodies.

16. A method of cleaning a chemical vapor deposition chamber, comprising:
introducing reactive species from a remote plasma source into the chemical vapor deposition chamber through a first inlet configured to provide reactive species from the remote plasma source into a processing region of the chemical vapor deposition chamber via a gas distribution assembly of the chemical vapor deposition chamber; and
introducing reactive species from the same or a different remote plasma source into the processing region of the chemical vapor deposition chamber through a second inlet configured to provide reactive species from the same or a different remote plasma source into the processing region of the chemical vapor deposition chamber while bypassing the gas distribution assembly.

17. The method of claim 16, wherein the reactive species are introduced into the chemical vapor deposition chamber through the first inlet at a first flow rate, the reactive species are introduced into the chemical vapor deposition chamber through the second inlet at a second flow rate, and the second flow rate is between about 1 and about 10 times greater than the first flow rate.

18. The method of claim 16, wherein the reactive species are introduced through the first inlet for a first period of time and the reactive species are introduced through the second inlet for a second period of time.

19. The method of claim 16, wherein the reactive species introduced through the second inlet are provided by the same remote plasma source that provides the reactive species to the first inlet.

20. The method of claim 16, wherein the reactive species introduced through the second inlet are provided by a different remote plasma source than the remote plasma source that provides the reactive species to the first inlet.
